(19) United States
(12) Patent Application Publication
(10) Pub. No.: US 2017/0309728 A1
(43) Pub. Date: Oct. 26, 2017

(54) METHOD FOR MANUFACTURING SEMICONDUCTOR DEVICE

(71) Applicant: Renesas Electronics Corporation, Tokyo (JP)

(72) Inventors: Tetsuya YOSHIDA, Tokyo (JP); Tetsuo ITO, Ibaraki (JP); Koji OGATA, Tokyo (JP); Hideki AONO, Tokyo (JP)

(73) Assignee: Renesas Electronics Corporation, Tokyo (JP)

(21) Appl. No.: 15/468,862

(22) Filed: Mar. 24, 2017

(30) Foreign Application Priority Data
Apr. 20, 2016 (JP) 2016-084421

(51) Int. Cl. H01L 29/66; H01L 27/12; H01L 21/84; H01L 21/762; H01L 21/266; H01L 29/06; H01L 21/265

(52) U.S. Cl. CPC H01L 29/66568; H01L 29/0649; H01L 27/1203; H01L 21/2652; H01L 21/76243; H01L 21/266; H01L 21/84

(57) ABSTRACT

In a process of implanting ions of an n-type impurity for threshold control into a semiconductor substrate surrounded by an element isolation portion, a resist pattern is formed such that the resist pattern covers a divot formed at a boundary portion of the element isolation portion with an SOI layer. Thus, since ions of the n-type impurity are not implanted into the divot, an etching rate of the divot in a cleaning process or the like is not accelerated, and etching can be suppressed. As a result, a BOX layer is prevented from becoming thin, so that degradation of a TDDB characteristic of the BOX layer can be prevented.

### CROSS-REFERENCE TO RELATED APPLICATION

The present application claims priority from Japanese Patent Application No. 2016-84421 filed on Apr. 20, 2016, the content of which is hereby incorporated by reference into this application.

### TECHNICAL FIELD OF THE INVENTION

The present invention relates to a method for manufacturing a semiconductor device, and is suitably used for manufacturing a semiconductor device using, for example, a silicon on thin buried oxide (SOTB) substrate.

### BACKGROUND OF THE INVENTION

Japanese Patent Application Laid-Open Publication No. 2014-236097 (Patent Document 1) discloses a technique for forming an epitaxial layer formed over a silicon on insulator (SOI) layer which is an upper portion of an SOI substrate such that the epitaxial layer has a broad width so as to cover ends of each upper surface of element isolation regions adjacent to the SOI layer.

### SUMMARY OF THE INVENTION

The SOTB substrate is constituted by a semiconductor substrate, a buried oxide (BOX) layer formed over the semiconductor substrate, and an SOI layer formed over the BOX layer. Since each of a thickness of the BOX layer and a thickness of the SOI layer is, for example, 10 to 20 nm, there is a problem that, if a divot is formed at a boundary portion of an element isolation portion with the SOI layer, the BOX layer becomes thin, electric field concentration occurs at an end of the BOX layer, and a time dependent dielectric breakdown (TDDB) characteristic of the BOX layer degrades.

Other objects and novel features of the present invention will be apparent from the description of the present specification and the accompanying drawings.

A method for manufacturing a semiconductor device according to an embodiment includes the steps of: preparing an SOI substrate which includes a semiconductor substrate, a BOX layer over the semiconductor substrate, and an SOI layer over the BOX layer; forming an opening portion in the SOI layer and the BOX layer and then, forming a trench in the semiconductor substrate under the opening portion; and forming an element isolation portion which is made of an insulating film buried in the opening portion and the trench. The method further includes the steps of: forming a semiconductor region for threshold control in the semiconductor substrate, by implanting ions of an impurity into the semiconductor substrate surrounded by the element isolation portion by using a resist pattern as a mask; forming a gate insulating film over the SOI layer after removing the resist pattern; and forming a gate electrode over the gate insulating film. The resist pattern is formed such that the resist pattern covers an upper surface of the element isolation portion and a boundary between the element isolation portion and the SOI layer.

According to the embodiment, reliability of a semiconductor device can be improved.

### BRIEF DESCRIPTIONS OF THE DRAWINGS

FIG. 1 is a cross-sectional view illustrating a manufacturing process of a semiconductor device according to a first embodiment;

FIG. 2 is a cross-sectional view illustrating the manufacturing process of the semiconductor device subsequent to the process illustrated in FIG. 1;

FIG. 3 is a cross-sectional view illustrating the manufacturing process of the semiconductor device subsequent to the process illustrated in FIG. 2;

FIG. 4 is a cross-sectional view illustrating the manufacturing process of the semiconductor device subsequent to the process illustrated in FIG. 3;

FIG. 5 is a cross-sectional view illustrating the manufacturing process of the semiconductor device subsequent to the process illustrated in FIG. 4;

FIG. 6 is a cross-sectional view illustrating the manufacturing process of the semiconductor device subsequent to the process illustrated in FIG. 5;

FIG. 7A is a plan view of resist pattern used when ion implantation for threshold voltage control is performed;

FIG. 7B is a plan view of resist pattern used when ion implantation for threshold voltage control is performed;

FIG. 8 is a cross-sectional view illustrating the manufacturing process of the semiconductor device subsequent to the process illustrated in FIG. 6;

FIG. 9 is a cross-sectional view illustrating the manufacturing process of the semiconductor device subsequent to the process illustrated in FIG. 8;

FIG. 10 is a cross-sectional view illustrating the manufacturing process of the semiconductor device subsequent to the process illustrated in FIG. 9;

FIG. 11 is a cross-sectional view illustrating the manufacturing process of the semiconductor device subsequent to the process illustrated in FIG. 10;

FIG. 12 is a cross-sectional view illustrating the manufacturing process of the semiconductor device subsequent to the process illustrated in FIG. 11;

FIG. 13 is a cross-sectional view illustrating the manufacturing process of the semiconductor device subsequent to the process illustrated in FIG. 12;

FIG. 14 is a cross-sectional view illustrating the manufacturing process of the semiconductor device subsequent to the process illustrated in FIG. 13;

FIG. 15 is a plan view illustrating the manufacturing process of the semiconductor device subsequent to the process illustrated in FIG. 13;

FIG. 16 is a cross-sectional view illustrating the manufacturing process of the semiconductor device subsequent to the process illustrated in FIG. 14 and FIG. 15;

FIG. 17 is a cross-sectional view illustrating the manufacturing process of the semiconductor device subsequent to the process illustrated in FIG. 16;

FIG. 18 is a cross-sectional view illustrating the manufacturing process of the semiconductor device subsequent to the process illustrated in FIG. 17;

FIG. 19 is a cross-sectional view illustrating the manufacturing process of the semiconductor device subsequent to the process illustrated in FIG. 18;

FIG. 20 is a cross-sectional view illustrating the manufacturing process of the semiconductor device subsequent to the process illustrated in FIG. 19;

FIG. 21 is a cross-sectional view illustrating a manufacturing process of a semiconductor device according to a second embodiment;

FIG. 22A is a plan view of resist pattern used when ion implantation for threshold voltage control is performed;

FIG. 22B is a plan view of resist pattern used when ion implantation for threshold voltage control is performed;

FIG. 23 is a cross-sectional view illustrating the manufacturing process of the semiconductor device subsequent to the process illustrated in FIG. 21;

FIG. 24 is a cross-sectional view illustrating the manufacturing process of the semiconductor device subsequent to the process illustrated in FIG. 23;

FIG. 25 is a cross-sectional view illustrating the manufacturing process of the semiconductor device subsequent to the process illustrated in FIG. 24;

FIG. 26 is a cross-sectional view illustrating the manufacturing process of the semiconductor device subsequent to the process illustrated in FIG. 25;

FIG. 27 is a cross-sectional view illustrating the manufacturing process of the semiconductor device subsequent to the process illustrated in FIG. 26;

FIG. 28 is a cross-sectional view illustrating the manufacturing process of the semiconductor device subsequent to the process illustrated in FIG. 27; and

FIG. 29 is a cross-sectional view illustrating the manufacturing process of the semiconductor device subsequent to the process illustrated in FIG. 28.

### DESCRIPTIONS OF THE PREFERRED EMBODIMENTS

In the embodiments described below, the invention will be described in a plurality of sections or embodiments when required as a matter of convenience. However, these sections or embodiments are not irrelevant to each other unless otherwise stated, and the one relates to the entire or a part of the other as a modification example, details, or a supplementary explanation thereof.

Also, in the embodiments described below, when referring to the number of elements (including number of pieces, values, amount, range, and the like), the number of the elements is not limited to a specific number unless otherwise stated or except the case where the number is apparently limited to a specific number in principle. The number larger or smaller than the specific number is also applicable.

Further, in the embodiments described below, it goes without saying that the components (including element steps) are not always indispensable unless otherwise stated or except the case where the components are apparently indispensable in principle.

Also, even when mentioning that constituent elements or the like are “made of A,” “made up of A,” “having A,” or “including A” in the embodiments below, elements other than A are of course not excluded except the case where it is particularly specified that A is the only element thereof. Similarly, in the embodiments described below, when the shape of the components, positional relation thereof, and the like are mentioned, the substantially approximate and similar shapes and the like are included therein unless otherwise stated or except the case where it is conceivable that they are apparently excluded in principle. The same goes for the numerical value and the range described above.

Also, components having the same function are, in principle, denoted by the same reference characters throughout the drawings for describing the embodiments below, and the repetitive description thereof is omitted. Also, in cross-sectional views and plan views, a size of each portion does not correspond to that of an actual device, and a specific portion is shown relatively largely so as to make the drawings easy to see, in some cases. In addition, hatching may be omitted even in a cross-sectional view so as to make the drawings easy to see, and hatching may be used even in a plan view so as to make the drawings easy to see.

Hereinafter, embodiments of the present invention will be described in detail with reference to the accompanying drawings.

### First Embodiment

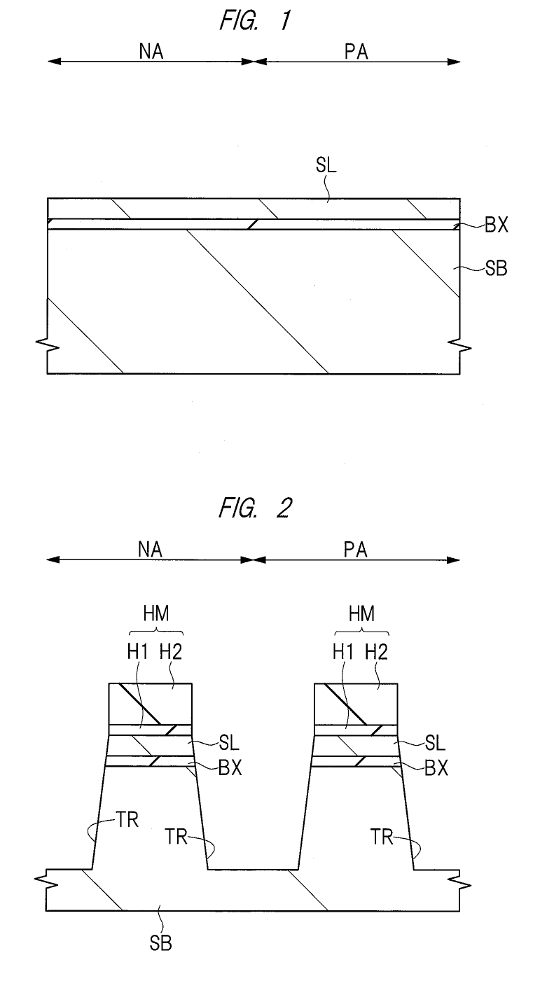

A method for manufacturing a semiconductor device according to a first embodiment will be described in order of processes with reference to FIGS. 1 to 20. In the first embodiment, a complementary metal oxide semiconductor (CMOS) device will be illustrated as an example of the semiconductor device. An n-channel metal oxide semiconductor field effect transistor (MOSFET) and a p-channel metal oxide semiconductor field effect transistor (MOSFET) constituting the CMOS device are abbreviated as nMOS and pMOS, respectively.

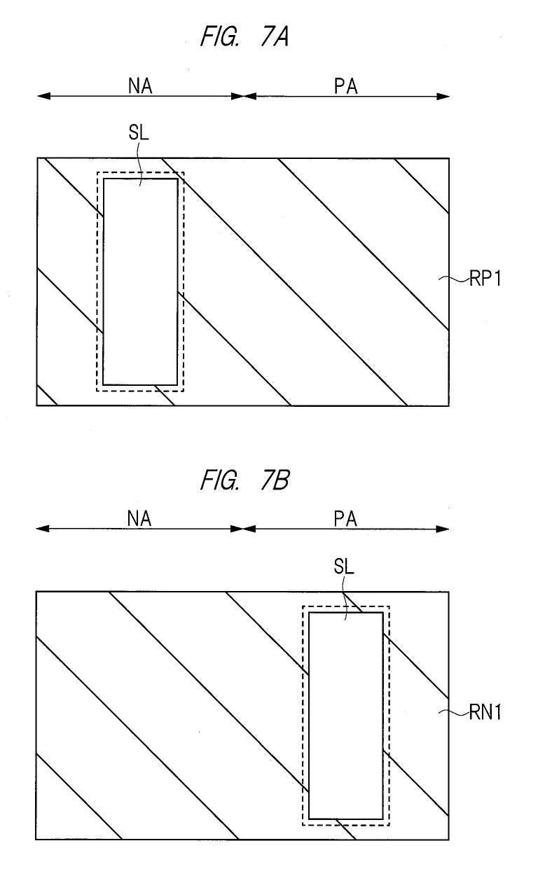

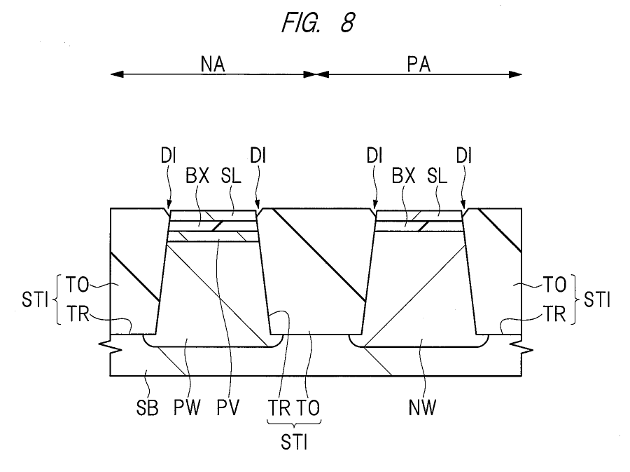

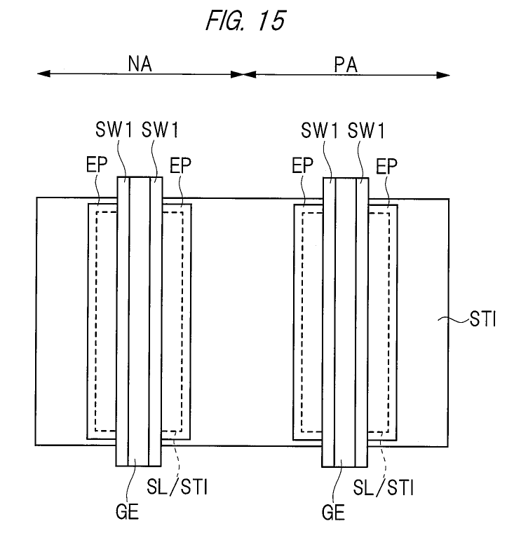

FIGS. 1 to 6, FIGS. 8 to 14, and FIGS. 16 to 20 are cross-sectional views illustrating manufacturing processes of the CMOS device over an SOI substrate. In the drawings, a region denoted by reference symbol NA is a region where the nMOS is formed, and a region denoted by reference symbol PA is a region where the pMOS is formed. FIGS. 7A and 7B are plan views of resist patterns used when ion implantation for threshold voltage control is performed. FIG. 15 is a plan view illustrating a manufacturing process of the CMOS device over the SOI substrate.

First, as illustrated in FIG. 1, a semiconductor substrate SB over which a BOX layer BX and an SOI layer SL are layered is prepared. The semiconductor substrate SB is a support substrate made of single crystal silicon (Si). The BOX layer BX over the semiconductor substrate SB is made of, for example, silicon oxide (SiO₂), and a thickness of the BOX layer BX is, for example, substantially 10 to 20 nm. The SOI layer SL over the BOX layer BX is made of, for example, single crystal silicon (Si), a thickness of the SOI layer SL is, for example, substantially 60 nm, and a resistance of the SOI layer SL is, for example, substantially 1 to 10 Ωcm. Note that the thickness of the SOI layer SL becomes smaller through subsequent processes.

In the present specification, the semiconductor substrate SB, the BOX layer BX, and the SOI layer SL are collectively referred to as the SOI substrate. In addition, the region where an upper surface of the semiconductor substrate SB is covered with the BOX layer BX and the SOI layer SL and the CMOS device is formed is referred to as an SOI region.

The SOI substrate can be formed by, for example, the following procedures. First, the SOI substrate can be formed by the silicon implanted oxide (SIMOX) method. In the method, ions of oxygen (O₂) are implanted at high energy into a main surface of the semiconductor substrate made of single crystal silicon (Si), silicon (Si) and oxygen (O) are combined by the subsequent heat treatment, and a buried oxide film is formed at a position slightly deeper than the main surface of the semiconductor substrate.

Alternatively, a semiconductor substrate made of single crystal silicon (Si) formed with a silicon oxide film over the main surface, and another semiconductor substrate made of single crystal silicon (Si) are prepared. Both of the semiconductor substrates are bonded and stuck together with the silicon oxide film interposed between the semiconductor substrates by applying high heat and a pressure. Then, one of the semiconductor substrates is polished to reduce a thickness of the semiconductor substrate, and accordingly, the SOI substrate can be formed.

Next, as illustrated in FIG. 2, a silicon oxide film H1 and a silicon nitride film H2 are sequentially deposited over the SOI layer SL. A thickness of the silicon oxide film H1 is, for example, substantially 10 to 20 nm. A thickness of the silicon nitride film H2 is, for example, substantially 100 nm.

Portions of the silicon oxide film H1 and the silicon nitride film H2 in a region where an element isolation portion is formed are removed, and a hard mask pattern HM made of the silicon oxide film H1 and the silicon nitride film H2 is formed. Subsequently, the SOI layer SL and the BOX layer BX are removed and an isolation trench TR is formed in the semiconductor substrate SB by the dry etching method using the hard mask pattern HM as a mask.

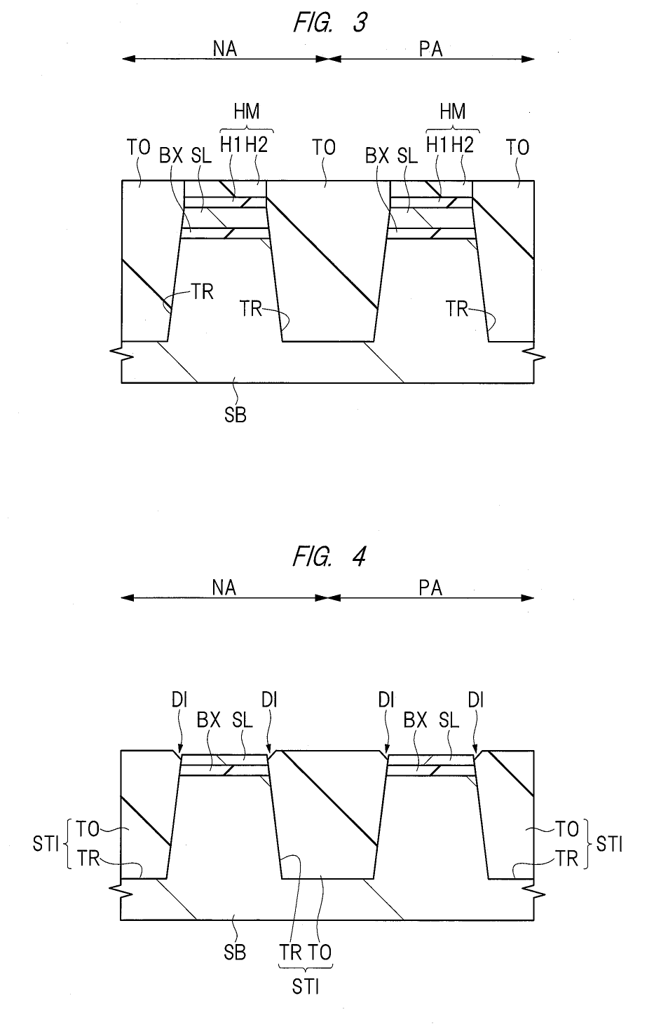

Next, as illustrated in FIG. 3, a silicon oxide film TO is formed over the SOI substrate by using, for example, the chemical vapor deposition (CVD) method such that the inside of the isolation trench TR is filled with the silicon oxide film TO. Then, an upper surface of the silicon oxide film TO is polished by using the chemical mechanical polishing (CMP) method.

Next, as illustrated in FIG. 4, the silicon nitride film H2 is removed, for example, by using hot phosphoric acid, and the silicon oxide film H1 is removed by the wet etching method using, for example, an aqueous solution containing hydrogen fluoride (HF) (hereinafter, simply referred to as hydrofluoric acid). Thus, an element isolation portion STI made of the silicon oxide film TO buried in the isolation trench TR is formed, and the SOI region covered with the BOX layer BX and the SOI layer SL is formed.

The region where the element isolation portion STI is formed is an inactive region which isolates the SOI region. That is, the shape of the SOI region in plan view is defined by the element isolation portion STI surrounding the SOI region.

Incidentally, when the silicon oxide film H1 is removed by wet etching, a front surface of the silicon oxide film TO buried in the isolation trench TR is also etched. Therefore, at a boundary portion of the element isolation portion STI with the SOI layer SL, in other words, in the vicinity of an interface between the SOI layer SL and the silicon oxide film TO at each end of an upper surface of the element isolation portion STI, the silicon oxide film TO is scraped, and a divot DI is formed.

This is because the density of the silicon oxide film TO may be lower in the end of the element isolation portion STI than in the center of the element isolation portion STI and because the end of the element isolation portion STI is located at a position where the silicon oxide film TO is easily removed by wet etching. Note that an upper surface of the divot DI is located lower than an upper surface of the SOI layer SL, but is located higher than an upper surface of the BOX layer BX.

Next, as illustrated in FIG. 5, a p-type impurity is selectively introduced into the semiconductor substrate SB in an nMOS formation region NA via the SOI layer SL and the BOX layer BX by ion implantation, and thus, a p-type well PW is formed. Similarly, an n-type impurity is selectively introduced into the semiconductor substrate SB in a pMOS formation region PA via the SOI layer SL and the BOX layer BX by ion implantation, and thus, an n-type well NW is formed.

Next, impurities for controlling a threshold voltage are introduced into the respective semiconductor substrates SB in the nMOS formation region NA and in the pMOS formation region PA.

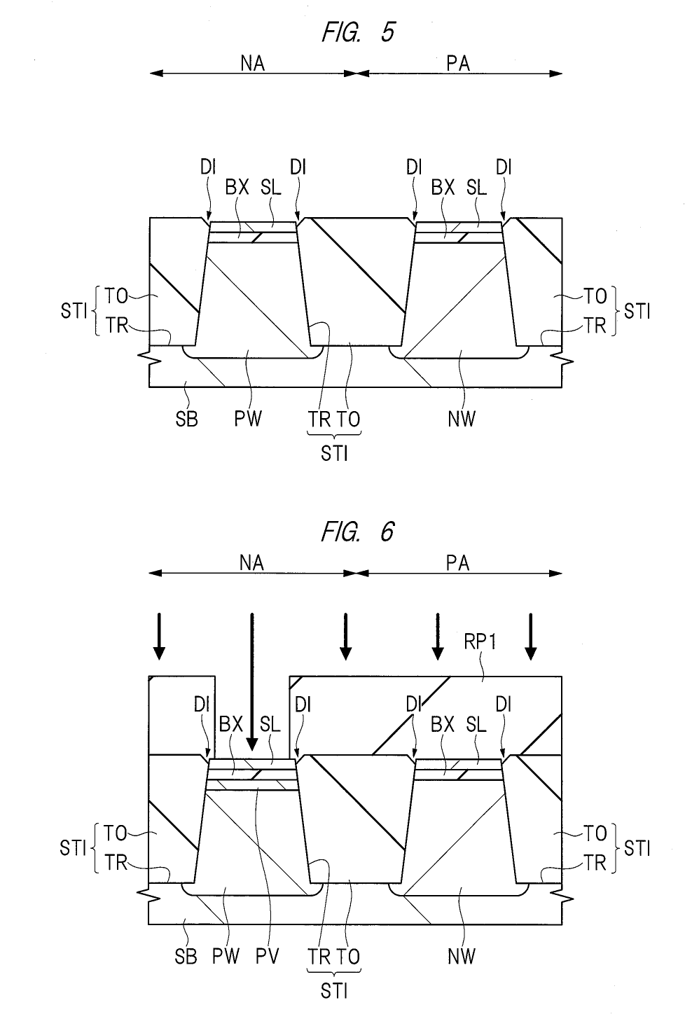

First, as illustrated in FIG. 6, a resist pattern RP1 is formed such that the resist pattern RP1 covers the pMOS formation region PA and the element isolation portion STI. FIG. 7A illustrates a plan view of the resist pattern RP1. In FIG. 7A, an outline of the upper surface of the SOI layer SL covered with the resist pattern RP1, that is, the boundary between the element isolation portion STI and the SOI layer SL is depicted by a dashed line.

The resist pattern RP1 is formed such that the SOI layer SL in the nMOS formation region NA is exposed and the resist pattern RP1 covers the divot DI formed at the boundary portion of the element isolation portion STI with the SOI layer SL. In practice, a thin insulating film is formed over the upper surface of the SOI layer SL as a protective film for ion implantation.

Specifically, the resist pattern RP1 is formed such that the resist pattern RP1 covers the SOI layer SL in the range from 0 nm to 5 nm from the boundary between the element isolation portion STI (a side surface of the trench portion TR constituting the element isolation portion STI) and the SOI layer SL in a direction toward the SOI layer SL. In other words, the resist pattern RP1 covers the element isolation portion STI, and the distance from the boundary between the element isolation portion STI and the SOI layer SL to an end of the resist pattern RP1 near the boundary on the SOI layer SL in the direction perpendicular to the boundary is 0 nm or more and 5 nm or less.

Next, a p-type impurity is selectively introduced into the semiconductor substrate SB (p-type well PW) in the nMOS formation region NA via the SOI layer SL and the BOX layer BX by ion implantation, and thus, a threshold voltage control region PV is formed. Examples of ion implantation conditions are as follows: the p-type impurity is boron (B), implantation energy is 20 to 40 keV, and a dose amount is 10¹³ to 10¹⁴ cm⁻².

Since the resist pattern RP1 covers the divot DI formed at the boundary portion of the element isolation portion STI with the SOI layer SL, ions of the p-type impurity are not implanted into the silicon oxide film TO formed with the divot DI.

Next, as illustrated in FIG. 8, the resist pattern RP1 is removed, and the upper surfaces of the element isolation portion STI and the SOI region are cleaned, for example, with hydrofluoric acid. Since ions of the p-type impurity are not implanted into the silicon oxide film TO formed with the divot DI, an etching rate of the silicon oxide film TO formed with the divot DI is not accelerated during cleaning, and the divot DI is hardly deepened.

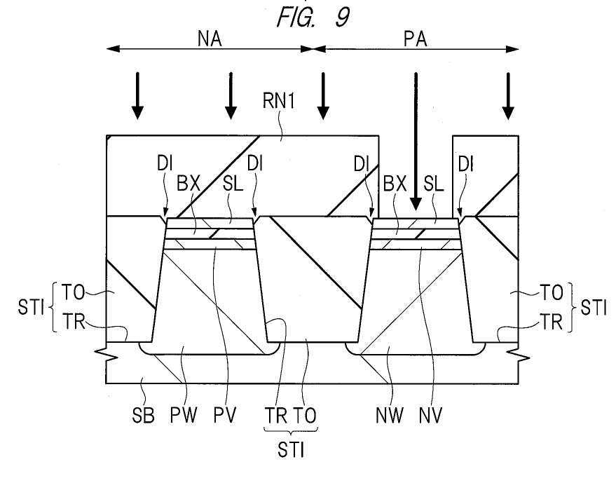

Next, as illustrated in FIG. 9, a resist pattern RN1 is formed such that the resist pattern RN1 covers the nMOS formation region NA and the element isolation portion STI. FIG. 7B illustrates a plan view of the resist pattern RN1. In FIG. 7B, an outline of the upper surface of the SOI layer SL covered with the resist pattern RN1, that is, the boundary between the element isolation portion STI and the SOI layer SL, is depicted by a dashed line.

The resist pattern RN1 is formed such that the SOI layer SL in the pMOS formation region PA is exposed and the resist pattern RN1 covers the divot DI formed at a boundary portion of the element isolation portion STI with the SOI layer SL. In practice, the thin insulating film is formed over the upper surface of the SOI layer SL as a protective film for ion implantation.

Specifically, the resist pattern RN1 is formed such that the resist pattern RN1 covers the SOI layer SL in the range from 0 nm to 5 nm from the boundary between the element isolation portion STI (a side surface of the trench portion TR constituting the element isolation portion STI) and the SOI layer SL in a direction toward the SOI layer SL. In other words, the resist pattern RN1 covers the element isolation portion STI, and the distance from the boundary between the element isolation portion STI and the SOI layer SL to an end of the resist pattern RN1 near the boundary on the SOI layer SL in the direction perpendicular to the boundary is 0 nm or more and 5 nm or less.

Next, an n-type impurity is selectively introduced into the semiconductor substrate SB (n-type well NW) in the pMOS formation region PA via the SOI layer SL and the BOX layer BX by ion implantation, and thus, a threshold voltage control region NV is formed. Examples of ion implantation conditions are as follows: the n-type impurity is arsenic (As) or phosphorus (P), implantation energy is 60 to 90 keV, a dose amount is 10¹³ to 10¹⁴ cm⁻².

Since the resist pattern RN1 covers the divot DI formed at the boundary portion of the element isolation portion STI with the SOI layer SL, ions of the n-type impurity are not implanted into the silicon oxide film TO formed with the divot DI.

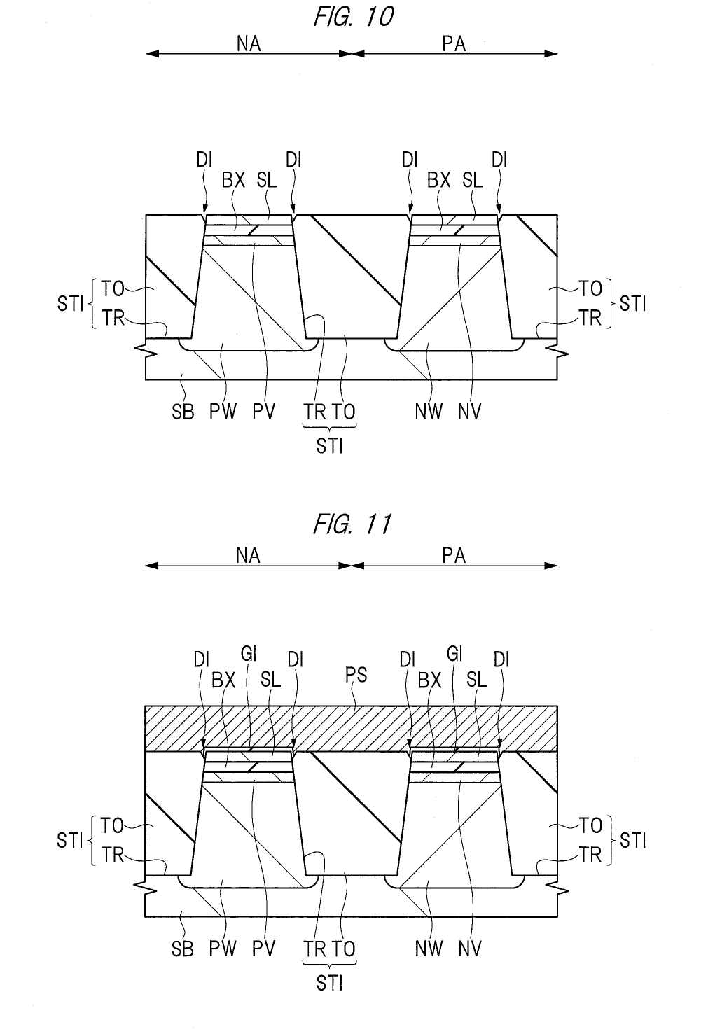

Next, as illustrated in FIG. 10, the resist pattern RN1 is removed, and the upper surfaces of the element isolation portion STI and the SOI region are cleaned, for example, with hydrofluoric acid. Since ions of the n-type impurity are not implanted into the silicon oxide film TO formed with the divot DI, the etching rate of the silicon oxide film TO formed with the divot DI is not accelerated during cleaning, and the divot DI is hardly deepened.

Next, as illustrated in FIG. 11, a gate insulating film GI made of, for example, silicon oxide (SiO₂) is formed over an exposed surface of the SOI layer SL by using, for example, the thermal oxidation method. A thickness of the gate insulating film GI is, for example, substantially 2 nm. In this case, even though the thickness of the SOI layer SL in film formation (initial film thickness) is substantially 60 nm, the thickness of the SOI layer SL is adjusted as a result of formation and removal of a sacrificial oxide film (protective film), and the like, and thus, the thickness becomes substantially 10 to 20 nm.

Next, a polycrystalline silicon film PS is formed over the SOI substrate by the CVD, for example. A thickness of the polycrystalline silicon film PS is, for example, substantially 100 nm.

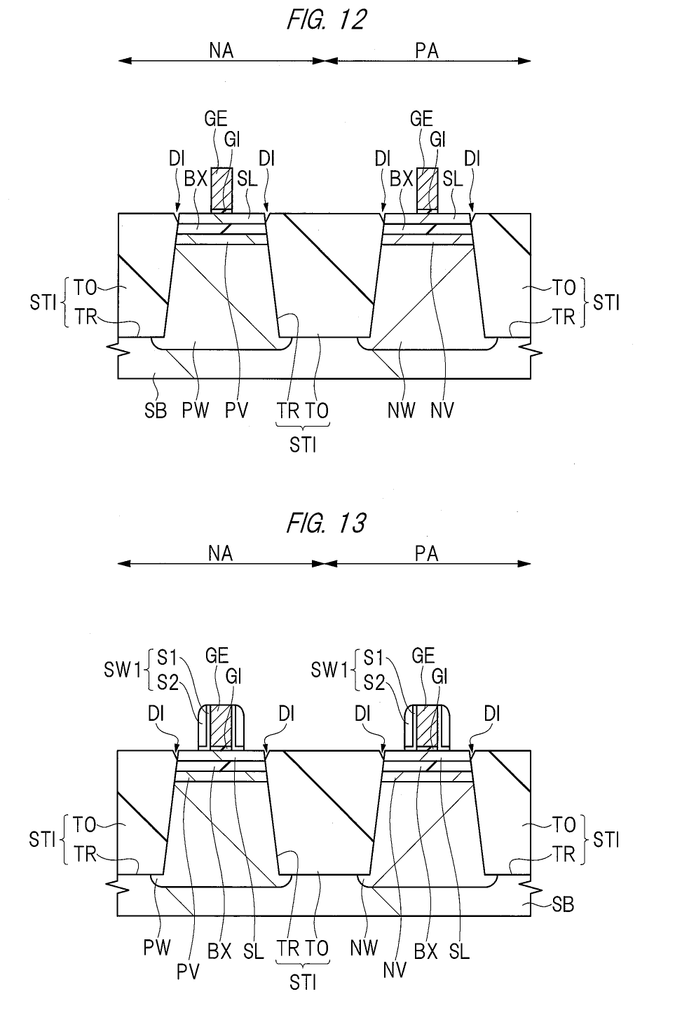

Next, as illustrated in FIG. 12, the polycrystalline silicon film PS is processed by the dry etching method using a resist pattern as a mask, and thus, a gate electrode GE made of the polycrystalline silicon film PS is formed. At this time, an upper surface of the gate insulating film GI and the upper surface of the silicon oxide film TO of the element isolation portion STI exposed due to etching of the polycrystalline silicon film PS are also slightly etched.

Then, the resist pattern is removed, and the upper surfaces of the element isolation portion STI and the SOI region are cleaned, for example, with hydrofluoric acid.

In the above-described ion implantation process for threshold voltage control (see FIGS. 6 to 10), when ions of the n-type impurity or the p-type impurity for threshold voltage adjustment are implanted into the silicon oxide film TO formed with the divot DI, the etching rate of the silicon oxide film TO formed with the divot DI is accelerated in cleaning and the like after removal of the resist pattern, and the divot DI is likely to be deepened.

When the divot DI is deepened, since the thickness of the SOI layer SL is thin, the divot DI may reach the BOX layer BX. That is, the upper surface of the divot DI may be lower than the upper surface of the BOX layer BX. In this case, since the thickness of the BOX layer BX is as thin as substantially 10 to 20 nm, electric field concentration is likely to occur at an end of the BOX layer BX, and a TDDB characteristic of the BOX layer degrades.

However, in the first embodiment, in the above-described ion implantation process for threshold voltage control (see FIGS. 6 to 10), ions of the n-type impurity or the p-type impurity for threshold voltage adjustment are not implanted into the silicon oxide film TO formed with the divot DI. Therefore, the etching rate of the silicon oxide film TO formed with the divot DI is not accelerated in cleaning and the like after removal of the resist pattern, and the divot DI is hardly deepened.

Therefore, since the divot DI does not reach the BOX layer BX, the upper surface of the divot DI can be maintained at a higher position than the upper surface of the BOX layer BX. Thus, electric field concentration hardly occurs at the end of the BOX layer BX, and degradation of the TDDB characteristic can be prevented.

Next, as illustrated in FIG. 13, a silicon oxide film S1 and a silicon nitride film S2 are sequentially deposited over the SOI substrate by the CVD, for example. Subsequently, the silicon nitride film S2 is selectively and anisotropically etched by using the silicon oxide film S1 as a stopper, and then, the exposed silicon oxide film S1 is removed by the wet etching method using, for example, hydrofluoric acid. Thus, a side wall SW1 made of the silicon oxide film S1 and the silicon nitride film S2 is formed over each of side surfaces of the gate electrode GE.

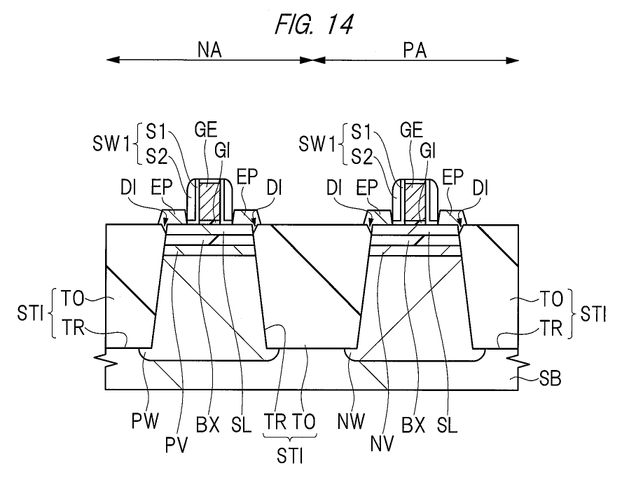

Next, as illustrated in FIG. 14, a stacked single crystal layer (hereinafter, referred to as an epitaxial layer) EP made of silicon (Si) or silicon-germanium (SiGe) is selectively formed over the exposed SOI layer SL by using, for example, a selective epitaxial growth method. A thickness of the epitaxial layer EP is, for example, substantially 30 nm.

Epitaxial growth is performed, for example, by using a batch-type vertical epitaxial growth device and processing a boat on which a plurality of semiconductor substrates are arranged, in a furnace serving as a reaction chamber. At this time, epitaxial growth is performed by supplying, for example, silane (SiH₄) gas as a film formation gas and chlorine (Cl) atom-containing gas as an etching gas to the furnace. For example, hydrochloric acid (HCl) gas or chlorine (Cl) gas may be used as the chlorine (Cl) atom-containing gas serving as the etching gas.

The film formation gas is silicon (Si) atom-containing gas, and the epitaxial layer EP is made of silicon as a main component. Also, the etching gas is used for preventing the upper surface of the element isolation portion STI from being covered with the excessively formed epitaxial layer EP. That is, by performing epitaxial growth and using the etching gas, the epitaxial layer EP is prevented from being formed excessively great.

However, as illustrated in FIGS. 14 and 15, the epitaxial layer EP is formed such that the epitaxial layer EP protrudes from the end of the upper surface of the SOI layer SL in a direction toward the element isolation portion STI adjacent to the end. That is, the epitaxial layer EP is formed not just over the SOI layer SL and formed to be wide such that the epitaxial layer EP extends over the upper surface of the end of the element isolation portion STI (including the upper surface of the divot DI). Therefore, the epitaxial layer EP is formed such that the divot DI is buried in the epitaxial layer EP.

In FIG. 15, the outline of the upper surface of the SOI layer SL covered with the epitaxial layer EP, that is, the boundary between the element isolation portion STI and the SOI layer SL, is depicted by a dashed line.

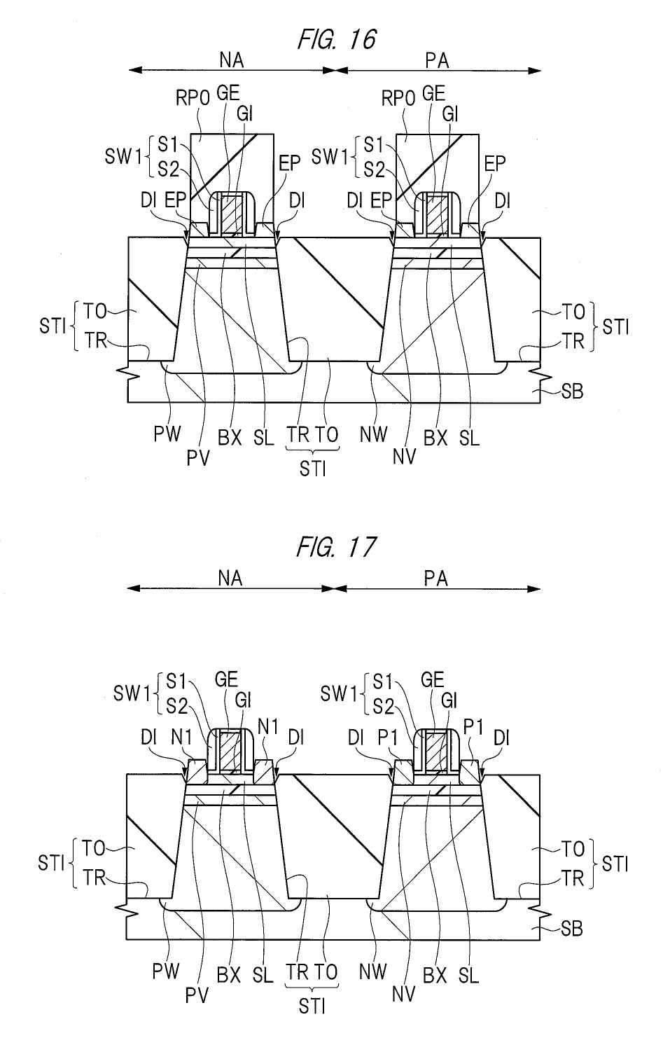

Next, as illustrated in FIG. 16, a resist pattern RP0 is formed such that the resist pattern RP0 covers the SOI substrate, and the epitaxial layer EP formed on the upper surface of the end of the element isolation portion STI (including the upper surface of the divot DI) and exposed from the resist pattern RP0 is selectively removed by using, for example, the dry etching method.

When a voltage is applied to the epitaxial layer EP in a state where the epitaxial layer EP in which the divot DI is buried is formed, electric field concentration is likely to occur at the end of the BOX layer BX, and the TDDB characteristic of the BOX layer BX degrades.

However, in the first embodiment, since the epitaxial layer EP which fills the divot DI is removed, no electric field is applied to the end of the BOX layer BX. Therefore, even in a case where the upper surface of the divot DI is lower than the upper surface of the BOX layer BX, degradation of the TDDB characteristic can be prevented.

Next, as illustrated in FIG. 17, after the resist pattern RP0 is removed, ions of the n-type impurity are implanted into the epitaxial layer EP and the SOI layer SL under the epitaxial layer EP in the nMOS formation region NA, and a first n-type region N1 with a relatively high concentration and constituting a part of a source/drain of the nMOS is formed in a self-aligned manner.

Similarly, ions of the p-type impurity are implanted into the epitaxial layer EP and the SOI layer SL under the epitaxial layer EP in the pMOS formation region PA, and a first p-type region P1 with a relatively high concentration and constituting a part of a source/drain of the pMOS is formed in a self-aligned manner.

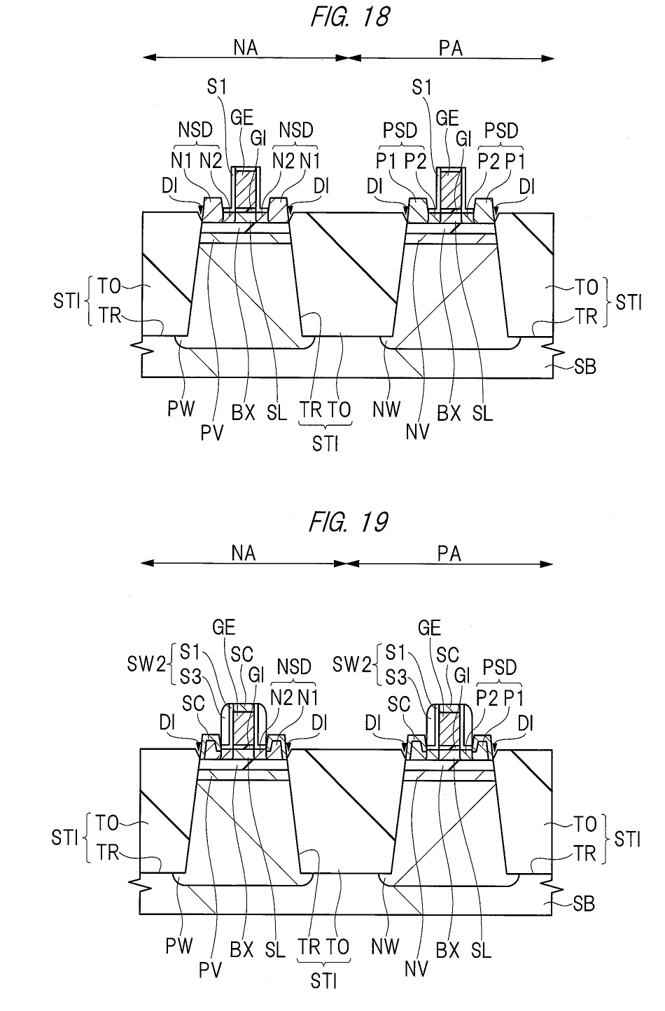

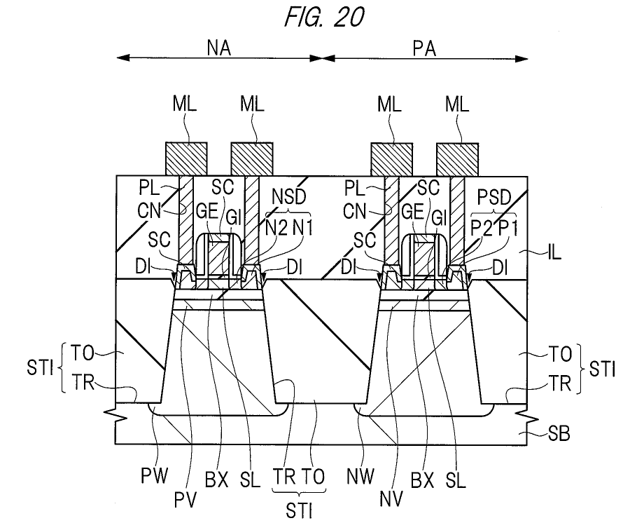

Note that the process of forming the first n-type region N1 and the first p-type region P1 may be performed immediately before a silicide formation process illustrated in FIG. 19 to be described later.

Next, as illustrated in FIG. 18, after the silicon nitride film S2 is selectively removed, ions of the n-type impurity are implanted into the SOI layer SL in the nMOS formation region NA, and a second n-type region N2 with a relatively lower concentration than the first n-type region N1 and constituting the other part of the source/drain of the nMOS is formed in a self-aligned manner.

Similarly, ions of the p-type impurity are implanted into the SOI layer SL in the pMOS formation region PA, and a second p-type region P2 with a relatively lower concentration than the first p-type region P1 and constituting the other part of the source/drain of the pMOS is formed in a self-aligned manner.

Then, the n-type impurity and the p-type impurity implanted through ion implantation are activated by heat treatment and diffused, so that a source/drain NSD of the nMOS constituted by the first n-type region N1 and the second n-type region N2 is formed and a source/drain PSD of the pMOS constituted by the first p-type region P1 and the second p-type region P2 is formed.

Next, as illustrated in FIG. 19, a silicon nitride film S3 is deposited over the SOI substrate, and then, the silicon nitride film S3 is selectively and anisotropically etched, so that a side wall SW2 made of the silicon oxide film S1 and the silicon nitride film S3 is formed over each of the side surfaces of the gate electrode GE.

Note that the above-described process of forming the first n-type region N1 and the first p-type region P1 may be performed and activation by heat treatment may be performed here.

Next, after a metal film such as a nickel film is deposited over the SOI substrate, heat treatment is performed, Nickel (Ni) is reacted with polycrystalline silicon (Si) constituting the gate electrode GE and single crystal silicon (Si) constituting the epitaxial layer EP, and thus, a silicide layer SC is formed. Subsequently, unreacted nickel (Ni) is removed by, for example, a mixed aqueous solution of hydrochloric acid (HCl) and hydrogen peroxide water (H₂O₂), heat treatment is further performed, and a phase of the silicide layer SC is controlled.

Thus, the low-resistance silicide layer SC is formed over an upper surface of the gate electrode GE and an upper surface of the epitaxial layer EP (sources/drains NSD and PSD).

Next, as illustrated in FIG. 20, an interlayer insulating film IL is deposited over the SOI substrate, and an upper surface of the interlayer insulating film IL is planarized.

Next, after a connecting hole CN reaching the gate electrode GE, the sources/drains NSD and PSD, and the like is formed in the interlayer insulating film IL, a plug PL is buried in the connecting hole CN. For example, the plug PL is formed in the connecting hole CN by forming, for example, a barrier layer made of titanium (Ti) and a conductor layer made of tungsten (W) over the interlayer insulating film IL such that the barrier layer and the conductor layer fill the inside of the connecting hole CN, and then, by polishing the barrier layer and the conductor layer over the interlayer insulating film IL.

Next, after a metal film such as an aluminum film or a copper film is deposited over the SOI substrate, the metal film is processed. Thus, a wire ML electrically connecting to the plug PL is formed.

Through the above processes, the CMOS device is substantially completed.

As described, according to the first embodiment, since the divot DI formed at the end of the upper surface of the element isolation portion STI is not deep enough to reach the BOX layer BX and the epitaxial layer EP is not formed at the divot DI, electric field concentration hardly occurs at the end of the BOX layer BX, and degradation of the TDDB characteristic of the BOX layer BX can be prevented. Thus, reliability of the semiconductor device can be improved.

Note that the first embodiment gives an example of the CMOS device having two characteristics, that is, the divot DI is formed such that the divot DI is not deep enough to reach the BOX layer BX and the epitaxial layer EP is not formed at the divot DI. However, even in each of a CMOS device having a characteristic in which a divot DI is formed such that the divot DI is not deep enough to reach a BOX layer BX and a CMOS device having a characteristic in which an epitaxial layer EP is not formed at a divot DI, electric field concentration at an end of the BOX layer BX is mitigated, so that degradation of the TDDB characteristic of the BOX layer BX can be prevented.

That is, the most effective way of preventing degradation of the TDDB characteristic is to execute both the solution for ion implantation illustrated in FIGS. 6 to 10, and the solution of selectively removing the epitaxial layer EP, illustrated in FIG. 16. However, degradation of the TDDB characteristic can be prevented by executing either of the solutions.

### Second Embodiment

A second embodiment differs from the above-described first embodiment in the method for introducing the impurities for controlling the threshold voltage into the semiconductor substrate SB in the nMOS formation region NA and the semiconductor substrate SB in the pMOS formation region PA. Hereinafter, points of difference from the above-described first embodiment will be mainly described.

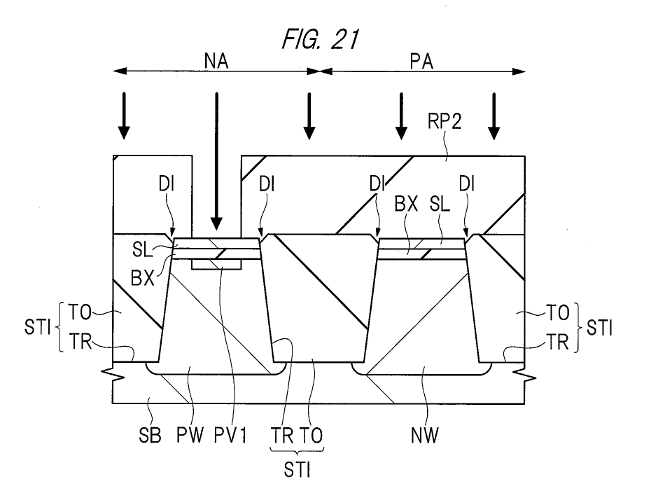

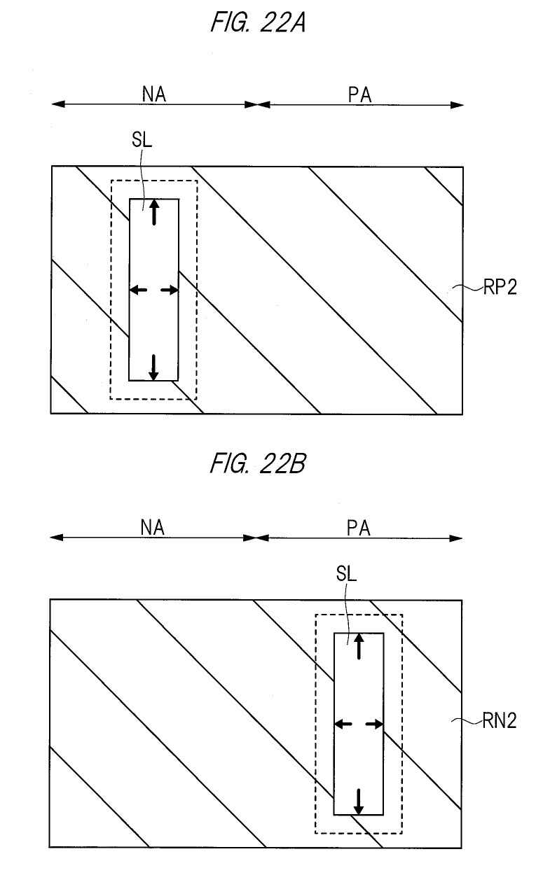

A method for manufacturing a semiconductor device according to the second embodiment will be described in order of processes with reference to FIGS. 21 to 29. FIG. 21 and FIGS. 23 to 29 are cross-sectional views illustrating manufacturing processes of a CMOS device over an SOI substrate. In the drawings, a region denoted by reference symbol NA is a region where an nMOS is formed, and a region denoted by reference symbol PA is a region where a pMOS is formed. FIGS. 22A and 22B are plan views of resist patterns used when ion implantation for threshold voltage control is performed.

First, similarly to the manufacturing processes described in the above-described first embodiment, an element isolation portion STI is formed in an SOI substrate. Furthermore, a p-type well PW is formed in the nMOS formation region NA and an n-type well NW is formed in the pMOS formation region PA.

Next, impurities for controlling a threshold voltage are introduced into the respective semiconductor substrates SB (p-type well PW and n-type well NW) in the nMOS formation region NA and the pMOS formation region PA.

First, as illustrated in FIG. 21, a resist pattern RP2 is formed such that the resist pattern RP2 covers the pMOS formation region PA and the element isolation portion STI. FIG. 22A illustrates a plan view of the resist pattern RP2. In FIG. 22A, an outline of an upper surface of an SOI layer SL covered with the resist pattern RP2, that is, the boundary between the element isolation portion STI and the SOI layer SL is depicted by a dashed line.

The resist pattern RP2 is formed such that a center portion of the SOI layer SL in the nMOS formation region NA is exposed and the resist pattern RP2 covers a divot DI formed at a boundary portion of the element isolation portion STI with the SOI layer SL. In practice, a thin insulating film is formed over the upper surface of the SOI layer SL as a protective film for ion implantation.

Specifically, the resist pattern RP2 is formed such that the resist pattern RP2 covers the SOI layer SL by extending 5 nm or more from the boundary between the element isolation portion STI (a side surface of a trench portion TR constituting the element isolation portion STI) and the SOI layer SL in a direction toward the SOI layer SL. In other words, the resist pattern RP2 covers the element isolation portion STI, and the distance from the boundary between the element isolation portion STI and the SOI layer SL to an end of the resist pattern RP2 near the boundary on the SOI layer SL in the direction perpendicular to the boundary is 5 nm or more.

Next, a p-type impurity is introduced in the direction vertical to a main surface of the semiconductor substrate SB by the ion implantation method using the resist pattern RP2 as a mask, and a threshold voltage control region PV1 is selectively formed in the semiconductor substrate SB (p-type well PW) in the nMOS formation region NA via the SOI layer SL and the BOX layer BX.

Since ions of the p-type impurity are not implanted into the semiconductor substrate SB immediately below the resist pattern RP2, ions of the p-type impurity are not implanted into a silicon oxide film TO formed with the divot DI. Note that, in this case, ions of the p-type impurity are implanted in the vertical direction with respect to the main surface of the semiconductor substrate SB; however, the direction is not limited to the vertical direction, and ions of the p-type impurity may be implanted in a direction oblique to the main surface of the semiconductor substrate SB.

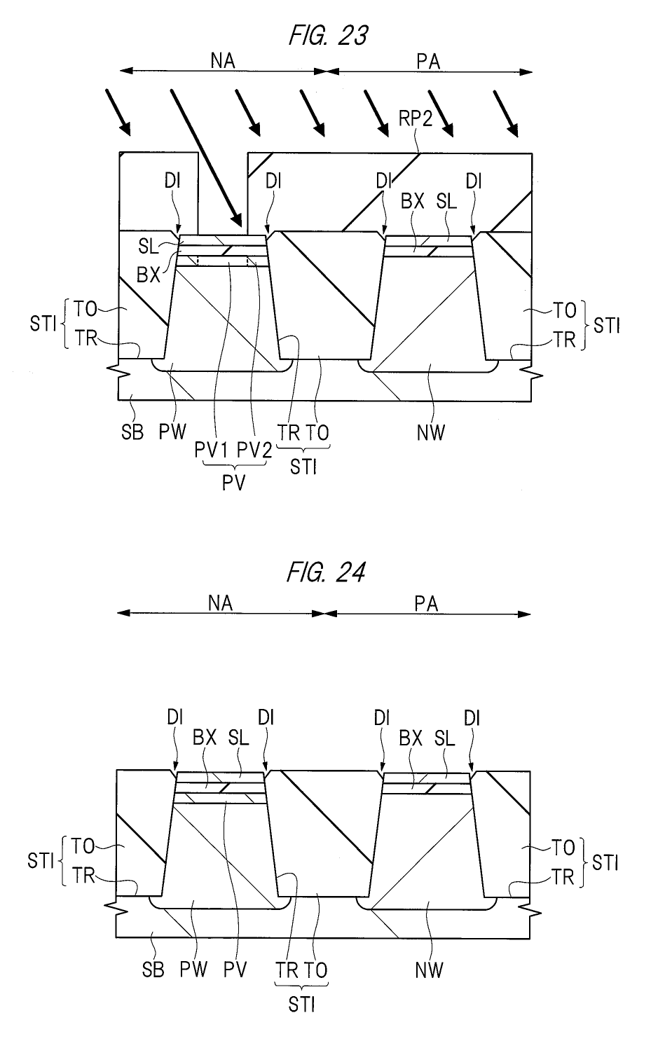

Next, as illustrated in FIG. 23, the p-type impurity is introduced in a direction oblique to the main surface of the semiconductor substrate SB by the ion implantation method using the resist pattern RP2 as a mask, and a threshold voltage control region PV2 is selectively formed in the semiconductor substrate SB (p-type well PW) in the nMOS formation region NA via the SOI layer SL and the BOX layer BX. As indicated by arrows in FIG. 22A, ions of the p-type impurity are implanted from four directions at an oblique implantation angle, so that the p-type impurity can be uniformly introduced into each end of an SOI region.

In this case, by setting an oblique implantation angle, ions of the p-type impurity are implanted into the semiconductor substrate SB (p-type well PW) immediately below the resist pattern RP2.

Therefore, by first ion implantation of the p-type impurity illustrated in FIG. 21 and second ion implantation of the p-type impurity illustrated in FIG. 23, a threshold voltage control region PV with a substantially uniform impurity concentration is formed in the semiconductor substrate SB (p-type well PW) under the BOX layer BX. Conditions for the first ion implantation of the p-type impurity and conditions for the second ion implantation of the p-type impurity may be identical to or different from each other as long as the threshold voltage control region PV with a substantially uniform impurity concentration can be formed.

As described above, the resist pattern RP2 reliably covers the divot DI, so that ions of the p-type impurity can be prevented from being implanted into the silicon oxide film TO formed with the divot DI. Even in this case, since the p-type impurity is introduced also into the semiconductor substrate SB immediately below the resist pattern RP2 by implanting ions of the p-type impurity in the oblique direction, the threshold voltage control region PV having a desired concentration and a desired depth can be formed.

Next, as illustrated in FIG. 24, the resist pattern RP2 is removed, and upper surfaces of the element isolation portion STI and the SOI region are cleaned, for example, with hydrofluoric acid. Since ions of the p-type impurity are not implanted into the silicon oxide film TO formed with the divot DI, an etching rate of the silicon oxide film TO formed with the divot DI is not accelerated during cleaning, and the divot DI is hardly deepened.

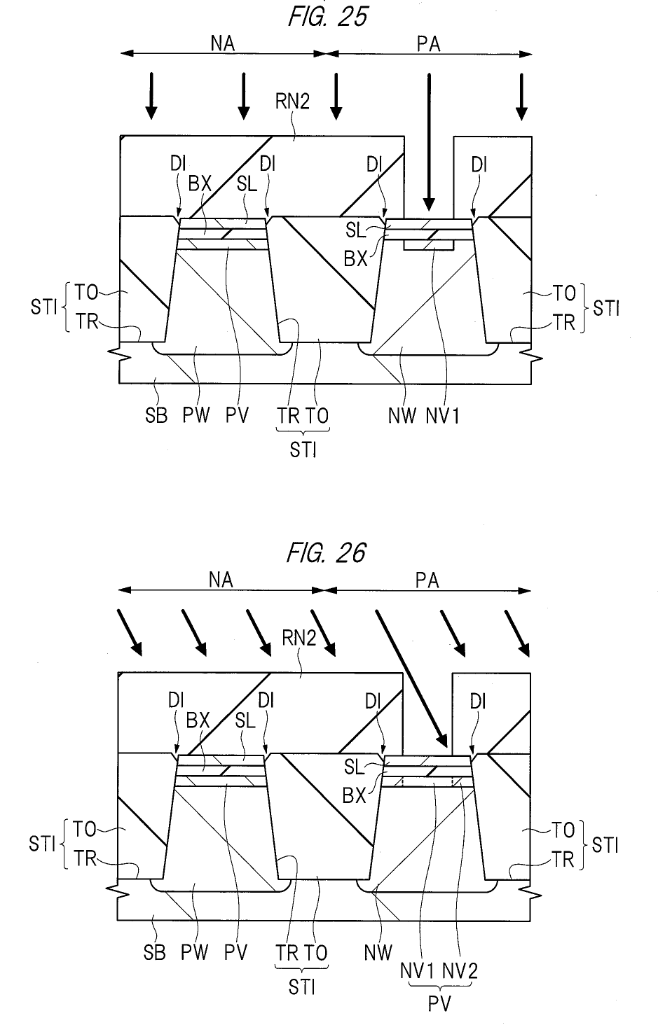

Next, as illustrated in FIG. 25, a resist pattern RN2 is formed such that the resist pattern RN2 covers the nMOS formation region NA and the element isolation portion STI. FIG. 22B illustrates a plan view of the resist pattern RN2. In FIG. 22B, an outline of the upper surface of the SOI layer SL covered with the resist pattern RN2, that is, the boundary between the element isolation portion STI and the SOI layer SL is depicted by a dashed line.

The resist pattern RN2 is formed such that a center portion of the SOI layer SL (in practice, the thin insulating film is formed over the upper surface of the SOI layer SL) in the pMOS formation region PA is exposed and the resist pattern RP2 covers the divot DI formed at the boundary portion of the element isolation portion STI with the SOI layer SL.

Specifically, the resist pattern RN2 is formed such that the resist pattern RN2 covers the SOI layer SL by extending 5 nm or more from the boundary between the element isolation portion STI (a side surface of the trench portion TR constituting the element isolation portion STI) and the SOI layer SL in a direction toward the SOI layer SL. In other words, the resist pattern RN2 covers the element isolation portion STI, and the distance from the boundary between the element isolation portion STI and the SOI layer SL to an end portion of the resist pattern RN2 near the boundary on the SOI layer SL in the direction perpendicular to the boundary is 5 nm or more.

Next, an n-type impurity is introduced in the direction vertical to the main surface of the semiconductor substrate SB by the ion implantation method using the resist pattern RN2 as a mask, and a threshold voltage control region NV1 is selectively formed in the semiconductor substrate SB (n-type well NW) in the pMOS formation region PA via the SOI layer SL and the BOX layer BX.

Since ions of the n-type impurity are not implanted into the semiconductor substrate SB immediately below the resist pattern RN2, ions of the n-type impurity are not implanted into the silicon oxide film TO formed with the divot DI. Note that, in this case, ions of the n-type impurity are implanted in the vertical direction with respect to the main surface of the semiconductor substrate SB; however, the direction is not limited to the vertical direction, and ions of the n-type impurity may be implanted in a direction oblique to the main surface of the semiconductor substrate SB.

Next, as illustrated in FIG. 26, the n-type impurity is introduced in a direction oblique to the main surface of the semiconductor substrate SB by the ion implantation method using the resist pattern RN2 as a mask, and a threshold voltage control region NV2 is selectively formed in the semiconductor substrate SB (n-type well NW) in the pMOS formation region PA via the SOI layer SL and the BOX layer BX. As indicated by arrows in FIG. 22B, ions of the n-type impurity are implanted from four directions at an oblique implantation angle, so that the n-type impurity can be uniformly introduced into each end of the SOI region.

In this case, by setting an oblique implantation angle, ions of the n-type impurity are implanted into the semiconductor substrate SB (n-type well NW) immediately below the resist pattern RN2.

Therefore, by first ion implantation of the n-type impurity illustrated in FIG. 25 and second ion implantation of the n-type impurity illustrated in FIG. 26, a threshold voltage control region NV with a substantially uniform impurity concentration is formed in the semiconductor substrate SB (n-type well NW) under the BOX layer BX. Conditions for the first ion implantation of the n-type impurity and conditions for the second ion implantation of the n-type impurity may be identical to or different from each other as long as the threshold voltage control region NV with a substantially uniform impurity concentration can be formed.

As described above, the resist pattern RN2 reliably covers the divot DI, so that ions of the n-type impurity can be prevented from being implanted into the silicon oxide film TO formed with the divot DI. Even in this case, the n-type impurity is introduced also into the semiconductor substrate SB immediately below the resist pattern RN2 by implanting ions of the n-type impurity in the oblique direction, so that the threshold voltage control region NV with a desired concentration and a desired depth can be formed.

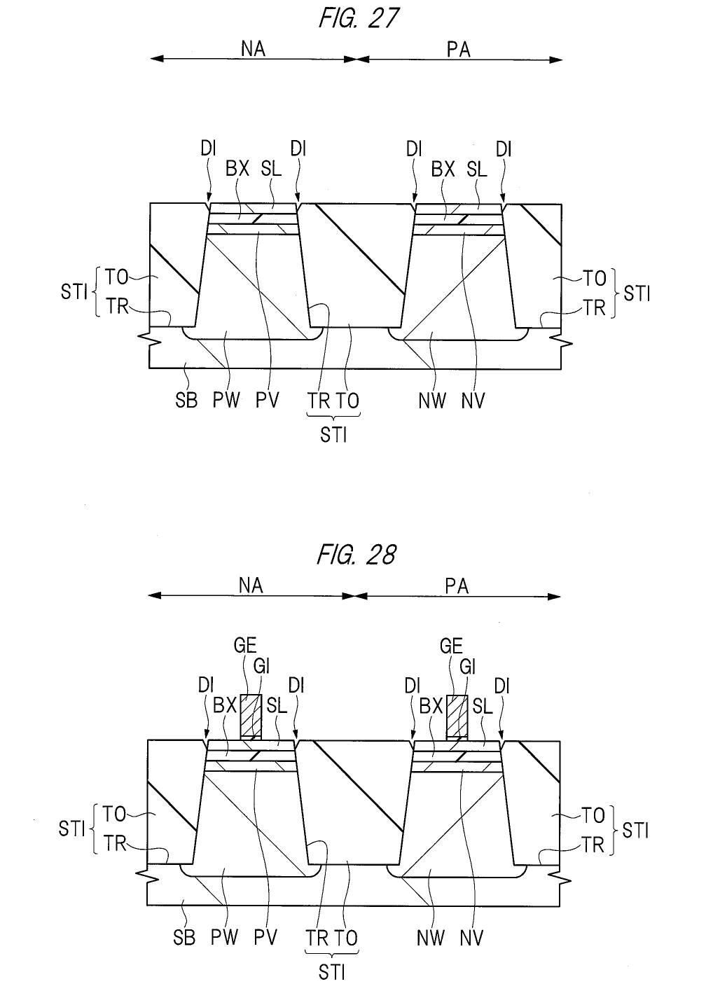

Next, as illustrated in FIG. 27, the resist pattern RN2 is removed, and the upper surfaces of the element isolation portion STI and the SOI region are cleaned, for example, with hydrofluoric acid. Since ions of the n-type impurity are not implanted into the silicon oxide film TO formed with the divot DI, the etching rate of the silicon oxide film TO formed with the divot DI is not accelerated during cleaning, and the divot DI is hardly deepened.

Next, similarly to the above-described first embodiment, as illustrated in FIG. 28, a gate insulating film GI made of silicon oxide (SiO₂) is formed, and a gate electrode GE made of polycrystalline silicon (Si) is formed.

In the second embodiment, in the above-described ion implantation process for threshold voltage control (see FIGS. 21 to 27), ions of the n-type impurity or the p-type impurity for threshold voltage adjustment are not implanted into the silicon oxide film TO formed with the divot DI. Therefore, in clearing after removal of the resist pattern or the like, the etching rate of the silicon oxide film TO formed with the divot DI is not accelerated, and the divot DI is hardly deepened.

Therefore, since the divot DI does not reach the BOX layer BX, the upper surface of the divot DI can be maintained at a higher position than the upper surface of the BOX layer BX. Thus, electric field concentration hardly occurs at the end of the BOX layer BX, and degradation of the TDDB characteristic of the BOX layer BX can be prevented.

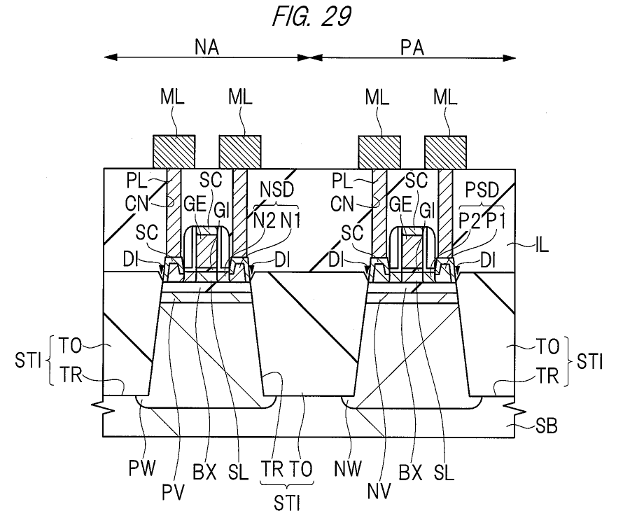

Then, similarly to the above-described first embodiment, as illustrated in FIG. 29, sources/drains NSD and PSN, a silicide layer SC, a plug PL, a wire ML, and the like are formed. Thus, the CMOS device is substantially completed.

As described above, according to the second embodiment, since the divot DI formed at the end of the upper surface of the element isolation portion STI is not deep enough to reach the BOX layer BX, electric field concentration hardly occurs at the end of the BOX layer BX, and degradation of the TDDB characteristic of the BOX layer BX can be prevented. Thus, reliability of the semiconductor device can be improved.

Note that, as described in the above-described first embodiment, a process of selectively removing an epitaxial layer EP formed at the divot DI may be performed in the manufacturing processes of the semiconductor device according to the second embodiment. By performing the process, electric field concentration at the end of the BOX layer BX is further mitigated, so that degradation of the TDDB characteristic of the BOX layer BX can be prevented.

In the foregoing, the invention made by the inventors of the present invention has been concretely described based on the embodiments. However, it is needless to say that the present invention is not limited to the foregoing embodiments and various modifications and alterations can be made within the scope of the present invention.

What is claimed is:

1. A method for manufacturing a semiconductor device, comprising the steps of:
(a) preparing an SOI substrate which includes a semiconductor substrate, a first insulating film over the semiconductor substrate, and a first semiconductor layer over the first insulating film;
(b) forming an opening portion in the first semiconductor layer and the first insulating film and then, forming a trench in the semiconductor substrate under the opening portion;
(c) forming an element isolation portion which is made of a second insulating film buried in the opening portion and the trench;
(d) forming a semiconductor region in the semiconductor substrate, by implanting ions of a first impurity via the first semiconductor layer and the first insulating film into the semiconductor substrate surrounded by the element isolation portion by using a resist pattern as a mask;
(e) forming a gate insulating film over the first semiconductor layer after removing the resist pattern; and
(f) forming a gate electrode over the gate insulating film,
wherein the resist pattern is formed such that the resist pattern covers an upper surface of the element isolation portion and a boundary between the element isolation portion and the first semiconductor layer.

2. The method for manufacturing a semiconductor device according to claim 1,
wherein the resist pattern is formed such that the resist pattern covers the first semiconductor layer in a range from 0 nm to 5 nm from the boundary in a direction toward the first semiconductor layer.

3. The method for manufacturing a semiconductor device according to claim 1,
wherein the step (d) includes the steps of:
(d1) forming a first semiconductor region at a center portion of the semiconductor substrate surrounded by the element isolation portion in plan view, by implanting ions of the first impurity by using the resist pattern as a mask; and
(d2) forming a second semiconductor region at each end of the semiconductor substrate surrounded by the element isolation portion in plan view, by implanting ions of the first impurity in an oblique direction by using the resist pattern as a mask.

4. The method for manufacturing a semiconductor device according to claim 3,
wherein the resist pattern is formed such that the resist pattern covers the first semiconductor layer by extending 5 nm or more from the boundary in a direction toward the first semiconductor layer.

5. The method for manufacturing a semiconductor device according to claim 1,
wherein the first impurity is arsenic or phosphorus.

6. The method for manufacturing a semiconductor device according to claim 1,
wherein a thickness of the first insulating film is 10 nm or more and 20 nm or less, and a thickness of the first semiconductor layer is 10 nm or more and 20 nm or less.

7. The method for manufacturing a semiconductor device according to claim 1,
wherein an upper surface of the second insulating film of the element isolation portion in the boundary is located higher than an upper surface of the first insulating film.

8. The method for manufacturing a semiconductor device according to claim 1, further comprising, after the step (f), the steps of:
(g) forming a second semiconductor layer by using an epitaxial growth method over an exposed upper surface and an exposed side surface of the first semiconductor layer;
(h) removing the second semiconductor layer on the upper surface of the element isolation portion; and
(i) forming a source and a drain by implanting ions of a second impurity into the second semiconductor layer and the first semiconductor layer under the second semiconductor layer.

9. The method for manufacturing a semiconductor device according to claim 8,
wherein, in the step (h), the second semiconductor layer formed over the side surface of the first semiconductor layer is removed.

10. A method for manufacturing a semiconductor device, comprising the steps of:
(a) preparing an SOI substrate which includes a semiconductor substrate, a first insulating film over the semiconductor substrate, and a first semiconductor layer over the first insulating film;
(b) forming an opening portion in the first semiconductor layer and the first insulating film and then, forming a trench in the semiconductor substrate under the opening portion;
(c) forming an element isolation portion which is made of a second insulating film buried in the opening portion and the trench;
(d) forming a semiconductor region in the semiconductor substrate, by implanting ions of a first impurity via the first semiconductor layer and the first insulating film into the semiconductor substrate surrounded by the element isolation portion;
(e) forming a gate insulating film over the first semiconductor layer;
(f) forming a gate electrode over the gate insulating film;
(g) forming a second semiconductor layer by using an epitaxial growth method over an exposed upper surface and an exposed side surface of the first semiconductor layer;
(h) removing the second semiconductor layer on an upper surface of the element isolation portion; and
(i) forming a source and a drain by implanting ions of a second impurity into the second semiconductor layer and the first semiconductor layer under the second semiconductor layer.

11. The method for manufacturing a semiconductor device according to claim 10,
wherein, in the step (h), the second semiconductor layer formed over the side surface of the first semiconductor layer is removed.
